(19) United States
(12) Patent Application Publication
(10) Pub. No.: US 2022/0333236 A1
(43) Pub. Date: Oct. 20, 2022

(54) SEMICONDUCTOR MANUFACTURING APPARATUS WITH IMPROVED PRODUCTION YIELD

(71) Applicant: Taiwan Semiconductor Manufacturing Co., Ltd., Hsinchu (TW)

(72) Inventors: Jia-Wei XU, Taichung City (TW); Ding-I Liu, Hsinchu (TW); Kai-Shiung Hsu, Hsinchu (TW); Yin-Bin Tseng, Hsinchu (TW)

(73) Assignee: Taiwan Semiconductor Manufacturing Co., Ltd., Hsinchu (TW)

(21) Appl. No.: 17/232,319

(22) Filed: Apr. 16, 2021

(51) Int. Cl. C23C 16/44; H01L 21/285; H01J 37/32; C23C 16/52; B08B 7/00; B08B 13/00

(52) U.S. Cl. CPC C23C 16/4405; H01L 21/28506; H01J 37/32871; H01J 37/32357; H01J 37/32724; H01J 37/32935; C23C 16/4408; C23C 16/52; B08B 7/0035; B08B 13/00; H01J 2237/332

(57) ABSTRACT

The present disclosure describes a semiconductor device manufacturing apparatus and a method for handling contamination in the semiconductor device manufacturing apparatus. The semiconductor device manufacturing apparatus can include a deposition apparatus and a processor. The deposition apparatus can include a chamber, a detection module configured to detect impurities in the chamber, and a gas scrubbing device configured to remove the impurities. The processor can be configured to receive, from the detection module, an impurity characteristic associated with the impurities; compare the impurity characteristic to a baseline characteristic; and instruct the gas scrubbing device to supply a decontamination gas in the chamber based on the comparison of the impurity characteristic to the baseline characteristic.

### BACKGROUND

With advances in semiconductor technology, there has been increasing demand for high yield of the deposition process for manufacturing semiconductor devices. To meet this demand, it is crucial to prevent deposition apparatus failures to ensure a reliable deposition process.

### BRIEF DESCRIPTION OF THE DRAWINGS

Aspects of this disclosure are best understood from the following detailed description when read with the accompanying figures.

FIG. 1 illustrates a plan view of a semiconductor device manufacturing apparatus, according to some embodiments.

FIG. 2 illustrates a chart for determining a contamination level in a semiconductor device manufacturing apparatus, according to some embodiments.

FIG. 3 illustrates a method for operating a semiconductor device manufacturing apparatus, according to some embodiments.

FIG. 4 illustrates a method for operating a semiconductor device manufacturing apparatus, according to some embodiments.

FIG. 5 illustrates a computer system for implementing various embodiments of the present disclosure, according to some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature on or over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

Semiconductor wafers are subjected to different fabrication processes (e.g., thin film deposition and chemical mechanical polishing) in different semiconductor manufacturing apparatus during the fabrication of semiconductor devices. The quality of semiconductor devices depends on the semiconductor manufacturing apparatuses' performance and ability to consistently achieve a high yield of operable semiconductor devices on semiconductor wafers.

An overall yield of manufacturing semiconductor devices depends not only on an accuracy of each fabrication process, but also on a cleanliness of the semiconductor manufacturing apparatuses. For example, the semiconductor manufacturing apparatus can be a deposition module, such as a chemical vapor deposition apparatus, that relies on an in-situ thermal distributor to ensure the semiconductor wafer's temperature uniformity during the deposition process conducted by the deposition module. However, the deposition process can introduce contaminants accumulating over the in-situ thermal distributor, thus degrading the thermal distributor's capability to maintain the semiconductor wafer's temperature uniformity during the deposition process. This degradation can cause thickness non-uniformity in films deposited by the deposition module, thus causing semiconductor device manufacturing defects.

The present disclosure is directed to a deposition apparatus and methods to address contaminants in the deposition apparatus. In some embodiments, the deposition apparatus can include a chamber and a thermal distributor housed in the chamber. The deposition apparatus can further include a gas scrubbing device housed in the chamber and configured to supply a decontamination gas to remove the contaminants from the thermal distributor. The deposition apparatus can further include a chuck configured to hold a semiconductor wafer over a front side of the chuck, where the gas scrubbing device is disposed over a rear side of the chuck. The deposition apparatus can further include a detection module configured to monitor the contaminants accumulated over the thermal distributor. Data recorded by the detection module can be received by a computer system configured to run a procedure to decontaminate the deposition apparatus. A benefit of the present disclosure, among others, is to provide a mechanism to dynamically decontaminate the deposition apparatus, thus improving the production yield of the deposition apparatus with an efficient usage of the decontamination gas.

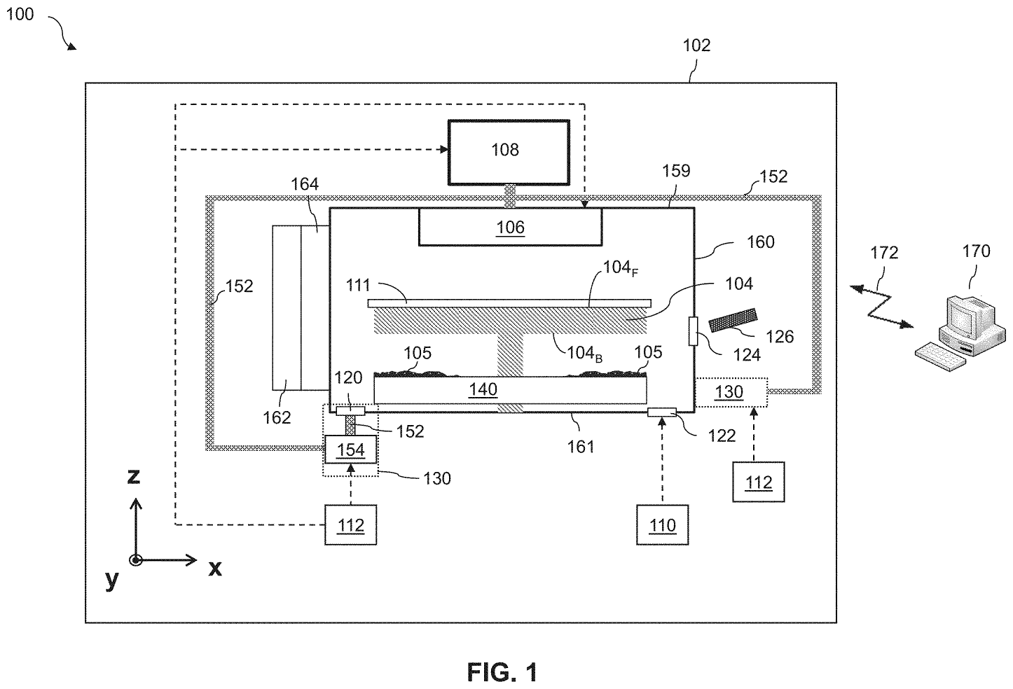

FIG. 1 illustrates a plan view of a semiconductor device manufacturing apparatus 100, according to some embodiments. Semiconductor device manufacturing apparatus 100 can include a processing module 102 configured to conduct a deposition process on a substrate 111 (e.g., a semiconductor wafer). In some embodiments, processing module 102 can conduct the deposition process to deposit a layer of material (not shown in FIG. 1) on substrate 111 (e.g., a semiconductor wafer), where the layer of material can be any suitable film, such as a layer of metallic material, a layer of semiconductor material, and a layer of dielectric material. Semiconductor device manufacturing apparatus 100 can further include a controller unit 170 configured to communicate with processing module 102 via a communication mechanism 172.

Processing module 102 can include a chamber 160 and a chuck 104 housed in chamber 160. Chamber 160 can be a processing chamber to provide a working environment, such as a vacuum environment and an environment filled with a processing gas, to conduct the deposition process on substrate 111. Chuck 104 can include a front side 104_{F} to hold substrate 111 to conduct the deposition process on substrate 111. Chuck 104 can further include a heating unit (e.g., an electric heater and a thermos gauge; not shown in FIG. 1) configured to heat substrate 111 to a target temperature to conduct the deposition process. In some embodiments, chuck 104 can further include a backside 104_{B} opposite to front side 104^{F}, where processing module 102 can further include a thermal distributor 140 disposed over chuck 104's backside 104_{B}. Thermal distributor 140 can receive thermal radiation from chuck 104 and can reflect the received thermal radiation towards substrate 111 to enhance substrate 111's temperature uniformity. Thermal distributor 140 can be made of any suitable material, such as a metallic plate or a mirror coating, that can reflect thermal radiation.

Processing module 102 can further include a showerhead 106 housed in chamber 160. Showerhead 106 can be configured as a gas cell to provide one or more gases in chamber 160 to conduct the deposition process on substrate 111. For example, showerhead 106 can provide a processing gas, such as tungsten hexafluoride, to deposit a layer of material (not shown in FIG. 1), such as a tungsten film, associated with the processing gas on substrate 111. In some embodiments, the one or more gases provided by showerhead 106 can further include an inert gas (e.g., nitrogen or air) or an etching gas (e.g., nitrogen trifluoride or hydrogen chloride) that can be associated with the deposition process or other processes, such as a decontamination process, conducted by processing module 102. In some embodiments, showerhead 106 can be configured as a plasma cell to provide a plasma for the deposition process or the etching process on substrate 111. In some embodiments, showerhead 106 can be configured as an effusion cell to provide an atomic beam or a molecular beam flux for the deposition process or the etching process on substrate 111. Showerhead 106 can be disposed at any suitable location in chamber 160. In some embodiments, showerhead 106 can be disposed over chuck 104's front side 104_{F}. In some embodiments, showerhead 106 can be disposed proximate to chamber 160's side 159 that is over chuck 104's front side 104_{F}. In some embodiments, showerhead 106 can be disposed proximate to chamber 160's side 159 that is over chuck 104's front side 104_{F}, where thermal distributor 140 can be disposed proximate to chamber 160's side 161, opposite to side 159, that is over chuck 104's backside 104_{B}. In some embodiments, showerhead 106 can provide a processing gas, such as tungsten hexafluoride, to deposit a layer of material (not shown in FIG. 1), such as a tungsten film, associated with the processing gas on substrate 111, while showerhead 106 can concurrently and unintentionally coat a layer of material 105 (herein referred as “residue 105”), such as a tungsten residue, associated with the processing gas over thermal distributor 140. Residue 105 can degrade thermal distributor 140's capability to reflect thermal radiation towards substrate 111. Therefore, residue 105 coated on thermal distributor 140 can degrade substrate 111's temperature uniformity, thus detrimentally impacting the production yield of the deposition process conducted by processing module 102 (e.g., residue 105 can cause thickness non-uniformity of the layer of material deposited on substrate 111 (not shown in FIG. 1)).

Processing module 102 can further include a gas scrubbing device 130 configured to provide a decontamination gas to remove residue 105 from thermal distributor 140. The decontamination gas supplied by gas scrubbing device 130 can include any suitable material that can react with residue 105. For example, residue 105 can include tungsten, where the decontamination gas supplied by gas scrubbing device 130 can include nitrogen trifluoride that can react and remove the tungsten-contained residue 105. In some embodiments, residue 105 can include a semiconductor material, such as silicon germanium, where the decontamination gas supplied by gas scrubbing device 130 can include hydrogen chloride that can react and remove the germanium-contained residue 105. Gas scrubbing device 130 can be disposed proximate to thermal distributor 140 to efficiently decontaminate thermal distributor 140. For example, thermal distributor 140 can be proximate to chamber 160's side 161 to efficiently remove residue 105 from thermal distributor 140. In some embodiments, both thermal distributor 140 and gas scrubbing device 130 can be disposed under chuck 104's backside 104_{B}, where showerhead 106 can be disposed over chuck 104's front side 104_{F}. In some embodiments, processing module 102 can include multiple gas scrubbing devices 130 to enhance the cleanliness of thermal distributor 140. For example, processing module 102 can include multiple gas scrubbing devices 130, where first and second groups of gas scrubbing devices 130 can be disposed over two opposite sides (e.g., alone x-direction and/or along y-direction) of thermal distributor 140. In some embodiments, processing module 102 can include multiple gas scrubbing devices 130, where a first group of gas scrubbing device 130 can be disposed under thermal distributor 140, and a second group of gas scrubbing device 130 can be disposed over thermal distributor 140.

Gas scrubbing device 130 can include a gas conduit 152, an opening 120 formed through sides of chamber 160, and a gas regulator 154 connecting opening 120 through gas conduit 152. Gas scrubbing device 130 can provide the decontamination gas to chamber 160 through opening 120, where gas regulator 154 can be configured to control the flow (e.g., the onset of gas flow, the flow rate, and/or the flow time) of the decontamination gas flowing through opening 120. In some embodiments, gas regulator 154 can include a valve (e.g., a pneumatic valve; not shown in FIG. 1) or a gas flow controller (e.g., a mass flow controller; not shown in FIG. 1). In some embodiments, gas scrubbing device 130 can be configured to purge chamber 160. For example, gas scrubbing device 130 can provide an inert gas (e.g., argon) to purge chamber 160, where the inert gas can be a carrier gas for processing module 102 to conduct the deposition process. In some embodiments, the inert gas can be a purging gas to expel gas residue (e.g., oxygen or moisture) in chamber 160. In some embodiments, processing module 102 can include multiple gas scrubbing devices 130. Each of the multiple gas scrubbing devices 130 can be disposed proximate to any portion of chamber 160's sides. In some embodiments, each of the multiple gas scrubbing devices 130 can be disposed over chamber 160′ side 161 (e.g., under chuck 104's backside 104_{B}) to efficiently remove residue 105 from thermal distributor 140.

Processing module 102 can further include a gas extraction system 110 and a gas supply system 112. Gas extraction system 110 can provide a target vacuum environment for chamber 160 by exhausting gas from chamber 160 through an gas outlet 122 formed on chamber 160's side. The black dash line from gas extraction system 110 to gas outlet 122 can illustrate a gas conduit. Gas extraction system 110 can include any suitable components, such as a vacuum pump (not shown in FIG. 1) and a gate valve (not shown in FIG. 1), that can control the gas extraction from chamber 160. Gas supply system 112 can be configured to supply a gas, such as a processing gas, an inert gas, an etching gas, and a decontamination gas, to chamber 160 to conduct the deposition process or the decontamination process. In some embodiments, gas supply system 112 can be coupled to showerhead 106 to conduct the deposition process on substrate 111, where the black dash line from gas supply system 110 to showerhead 106 can illustrate a gas conduit. In some embodiments, gas supply system 112 can be coupled to gas purging device 130 through gas regulator 154 to conduct the purging process to purge chamber 160 or conduct the decontamination process to remove residue 105 from thermal distributor 140, where the black dash line from gas supply system 112 to gas purging device 130 can illustrate a gas conduit. Gas supply system 112 can include any suitable components, such as a gas source (e.g., a gas cylinder; not shown in FIG. 1) and a gas flow controller (e.g., a mass flow controller; not shown in FIG. 1) that can provide the gas to chamber 160.

Processing module 102 can further include a remote plasma source 108 configured to provide a radical associated with a processing gas or a radical associated with a decontamination gas to respectively conduct the deposition process or the decontamination process in chamber 160. In some embodiments, gas supply source 108 can be coupled to showerhead 106 through remote plasma source 108, where the black dash line from gas supply system 110 to remote plasma source 108 can illustrate a gas conduit. Accordingly, showerhead 106 that couples to remote plasma source 108 can be configured as an effusion cell to provide atomic/molecular beam fluxes to chamber 160 to conduct the deposition process on substrate 111. In some embodiments, gas supply source 108 can be coupled to gas purging device 130 through remote plasma source 108. Accordingly, the decontamination gas (e.g., nitrogen trifluoride) supplied by gas scrubbing device 130, coupled to remote plasma source 108, can be in an atomic form or an radical form (e.g., F, F₂, NFₓ, N, or N₂) to enhance the removal of residue 105 from thermal distributor 140. In some embodiments, each of remote plasma source 108, showerhead 106, and gas purging device 130 can be interconnected with each other through gas conduit 152.

Processing module 102 can further include a detection module 126 configured to detect an impurity level (e.g., residue 105's level) in chamber 160. In some embodiments, detection module 126 can monitor a surface coverage of residue 105 coated over thermal distributor 140's surface. Detection module 126 can be disposed outside chamber 160. For example, chamber 160 can include a viewport 124 formed through chamber 160's side, where detection module 126 can be disposed proximate to viewport 124 and outside chamber 160. In some embodiments, viewport 124 can be formed through chamber 160's sides and positioned at a higher vertical (e.g., in the z-direction) position over thermal distributor 140's top surface that faces chuck 104. Accordingly, detection module 126 can be configured to monitor a surface coverage of residue 105 coated over the thermal distributor 140's top surface through viewport 124. Detection module 126 can be any suitable sensor that can record a signature associated with the surface coverage of residue 105 coated over thermal distributor 140. For example, detection module 126 can include a temperature sensor, such as a fiber optic temperature sensor, a pyrometer, and any suitable remote temperature sensor configured to record a temperature signature of thermal distributor 140. Since residue 105 coated over thermal distributor 140 can degrade thermal distributor 140's capability to reflect thermal radiation, thermal distributor 140's surface temperature can be affected by the coated residue 105. Accordingly, detection module 126 that includes the temperature sensor can monitor a surface coverage of residue 105 coated over thermal distributor 140.

In some embodiments, detection module 126 can include an image sensor, such as a charge coupled device (CCD) sensor, configured to record a visual signature of thermal distributor 140's surface, such as a visual signature of thermal distributor 140's top surface that faces chuck 104. The visual signature can include images or videos of residue 105 coated over thermal distributor 140, thus representing a surface coverage of residue 105 coated over thermal distributor 140. The images/videos recorded by detection module 126 can have any suitable format, such as a suitable resolution (e.g., 640 pixels×480 pixels), greyscale (e.g., 256 combinations of shades of gray), chrominance, or frame rate (e.g., 30 pictures per second).

In some embodiments, detection module 126 can include an optical module, such as an optical interferometer, configured to transmit and receive one or more optical signals associated with measuring a surface coverage of residue 105 or a thickness of residue 105 on thermal distributor 140. For example, detection module 126 can be configured to transmit an optical signal towards thermal distributor 140's surface and receive another optical signal reflected, deflected, or refracted from the thermal distributor 140's surface. An intensity difference or a phase difference between the transmitted and received optical signal can be associated with the surface coverage of residue 105 on thermal distributor 140.

Processing module 102 can further include a loading port 162 and a transfer module 164. Loading port 162 can be configured to accommodate a wafer storage device (e.g., a front opening unified pod (FOUP)) for temporarily storing a batch of semiconductor wafers in a controlled environment with a designated gas pressure, gas ambient, humidity, and/or temperature during intervals between the semiconductor device manufacturing processes. Loading port 162 can include a stage (not shown in FIG. 1) to hold the wafer storage device. In some embodiments, loading port 162 can include a chamber (not shown in FIG. 1) to accommodate the wafer storage device in a vacuum or an inert gas (e.g., under nitrogen ambient) environment. Transfer module 164 can be configured to provide a central transfer conduit to transfer substrate 111 between loading port 162 and chamber 160. In some embodiments, transfer module 164 can include a robotic arm and a wafer orientation stage (both not shown in FIG. 1), where the robotic arm can be configured to transfer wafers between loading port 162, the wafer orientation stage, and chamber 160. In some embodiments, transfer module 164 can be configured to be at atmospheric pressure or at a vacuum environment.

Controller unit 170 can include any suitable computer system (e.g., workstation or portable electronic device) to store programs and data for various operations of semiconductor device manufacturing apparatus 100. Controller unit 170 can instruct semiconductor device manufacturing apparatus 100 to conduct various fabrication processes on a substrate, such as on substrate 111. For example, controller unit 170 can be configured to instruct processing module 102 to conduct the deposition process on substrate 111. In some embodiments, controller unit 170 can be configured to instruct processing module 102 to conduct a decontamination process to remove residue 105 from processing module 102, such as removing residue 105 from thermal distributor 140. The different functions of controller unit 170 should not be limited by the embodiments of the present disclosure. Communication mechanism 172 can include any suitable network connection between controller unit 170 and each module of semiconductor device manufacturing apparatus 100. For example, communication mechanism 172 can include a local area network (LAN), a WiFi network, and/or a wired network. In some embodiments, controller unit 170 can transmit control signals through communication mechanism 172 to control each element (e.g., chuck 104, gas purging device 130, or detection module 126) of processing module 102.

In some embodiments, controller unit 170 can be configured to perform a computing procedure to analyze the data, such as the temperature signature data, the visual signature data, and the optical data, to determine the contamination characteristic of thermal distributor 140. The computer procedure can include one or more mathematical operations, a pattern recognition procedure, a big data mining procedure, or a machine learning procedure, such as a neural network algorithm or a regression algorithm, to analyze, classify, and/or cluster the visual signature/optical/acoustic/fluid movement/vacuum signature data.

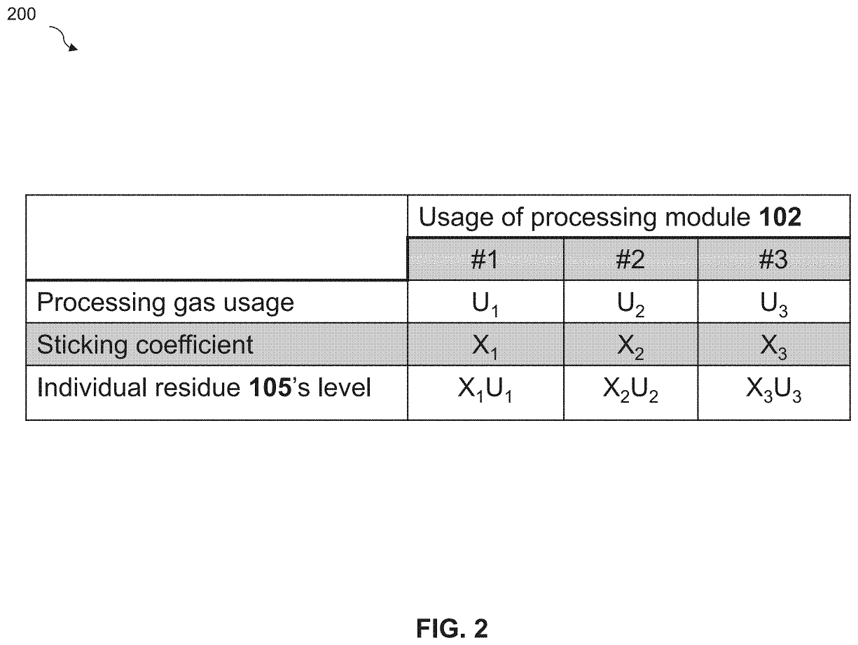

FIG. 2 illustrates a chart 200 to determine a contamination level of residue 105 at thermal distributor 140 based on usage of processing module 102, according to some embodiments. As shown in FIG. 2, chart 200 indicates that processing module 102 has performed three deposition processes. Each of the deposition processes can be associated with usage of a processing gas that deposits a film on substrate 111 and coats a respective residue 105 on thermal distributor 140. The processing gas of each of the deposition processes can be the same or different from each other. Even though three deposition processes are performed, chart 200 can record any number of deposition processes performed by processing module 102.

Each of the processing gas usages U₁-U₃ can be determined based on a volume of the processing gas outputted by showerhead 106. In some embodiments, each of the processing gas usages U₁-U₃ can be proportional to a flow rate of the processing gas transported to remote plasma source 108 and showerhead 106, where the flow rate can be measured by gas supply system 112. In some embodiments, each of the processing gas usages U₁-U₃ can be a product of the flow rate and a flow time of the processing gas, where the flow time can be determined by controller unit 170 and/or gas supply system 112.

The processing gases can have respective sticking coefficients X₁-X₃. Each of the sticking coefficients X₁-X₃ can be a ratio of the number of atoms/molecules of the processing gas that adsorb to thermal distributor 140's surfaces to the total number of atoms/molecules of the processing gas. In some embodiments, each of the sticking coefficients X₁-X₃ can be determined based on the temperature (e.g., chuck 104's temperature and/or thermal distributor 140's temperature) associated with the respective deposition process. For example, each of the sticking coefficients X₁-X₃ can be positively correlated (e.g., substantially linear proportion or exponential proportion) to the temperature associated with the deposition process. In some embodiments, each of the sticking coefficients X₁-X₃ can be determined based on the operating pressure in chamber 160 during the deposition process. For example, each of the sticking coefficients X₁-X₃ can be positively correlated (e.g., substantially linear proportion) to the operating pressure in chamber 160 during deposition process.

Each of the deposition processes can contribute a respective amount of residue 105 coated on thermal distributor 140. For example, each of the individual residue 105's level can be proportional to a usage (e.g., U₁) of the respective processing gas. In some embodiments, each of the individual residue 105's level can be proportional to a weighted usage of the processing gas (e.g., U₁X₁). A contamination level associated with a total residue 105 adhered to thermal distributor 140 can therefore be proportional to a weighted sum of the processing gases' usages (e.g., U₁-U₃) based on the respective sticking coefficients (e.g., X₁-X₃). In other words, a processing gas with a high sticking coefficient can produce more residue 105, thus resulting in a higher contamination level. Accordingly, as illustrated in chart 200, the contamination level contributed by each of the three deposition processes can be proportional to a cumulative sum (e.g., X₁U₁+X₂U₂+X₃U₃) of each individual residue 105's level.

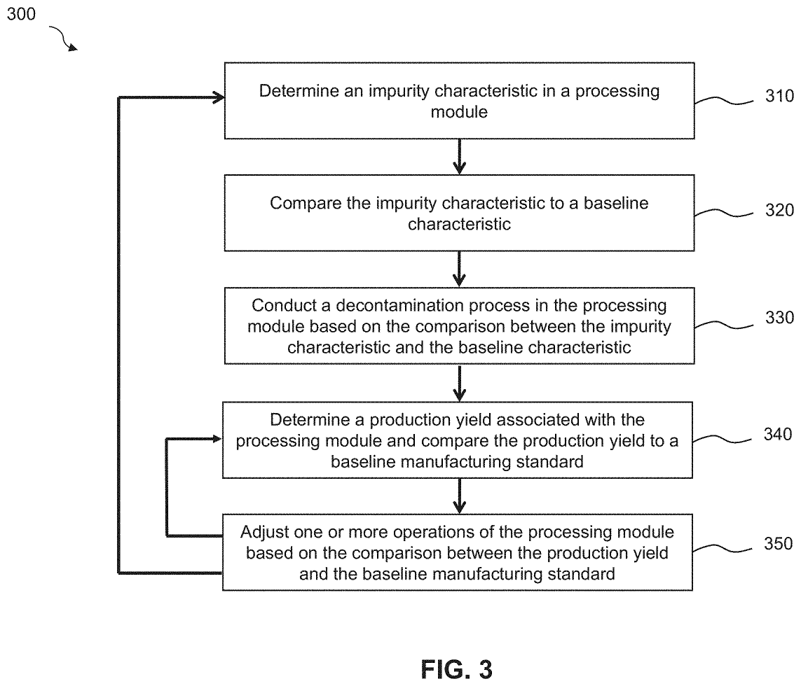

FIG. 3 is a method 300 for operating a processing module of a semiconductor device manufacturing apparatus as described with reference to FIGS. 1 and 2, according to some embodiments. Operations shown in method 300 are not exhaustive; other operations can be performed as well before, after, or between any of the illustrated operations. Moreover, not all operations may be needed to perform the disclosure provided herein. Further, some of the operations may be performed simultaneously, or in a different order than shown in FIG. 3. In some embodiments, operations of method 300 can be performed in a different order. Variations of method 300 are within the scope of the present disclosure.

Method 300 begins with operation 310, where an impurity characteristic in the processing module is determined. The impurity characteristic can include a surface coverage of a contaminant (e.g., residue 105) in process module 102. In some embodiments, the impurity characteristic can include a surface coverage of the contaminant (e.g., residue 105) coated over process module 102's thermal distributor 140. In some embodiments, operation 310 can be performed concurrently with a fabrication process, such as a deposition process, conducted by processing module 102. In some embodiments, operation 310 can be performed while processing module 102 is idle (e.g., chuck 104 does not hold substrate 111).

The process of determining the impurity characteristic can include collecting a thermal signature of elements included in process module 102. For example, the process of determining the impurity characteristics can include measuring, via detection module 126, the thermal signature (e.g., temperature) of thermal distributor 140. As previously discussed, residue 105 coated over thermal distributor 140 can degrade thermal distributor 140's capability to reflect thermal radiation, thus causing a temperature drop of thermal distributor 140. Accordingly, by measuring thermal distributor 140's temperature, the coverage of reside 105 over thermal distributor 140 (e.g., the impurity characteristic) can be determined. In some embodiments, the process of determining the impurity characteristics can include measuring a temperature of thermal distributor 140's surface that faces chuck 104. In some embodiments, the process of determining the impurity characteristics can include measuring thermal distributor 140's surface temperature, while chuck 104 can be operating at a temperature, such as from about 100° C. to about 900° C., from about 250° C. to about 650° C., and from about 300° C. to about 600° C., suitable for a deposition process. If chuck 104's temperature is below the above-noted lower limits, process module 102 may not be able to conduct the deposition process. If chuck 104's temperature is beyond the above-noted upper limits, the film formed by the deposited process may degrade. In some embodiments, the process of determining the impurity characteristics can include measuring a temperature of a portion of chamber 160's sides proximate to chuck 104. In some embodiments, details of operation 310 can at least be referred to the description of thermal distributor 140 and detection module 126 shown at FIGS. 1 and 2.

In some embodiments, the process of determining the impurity characteristic can include collecting a visual signature of elements in process module 102. For example, the process of determining the impurity characteristic can include collecting a visual signature (e.g., images or videos) of thermal distributor 140's surface via detection module 126. The visual signature can include information of color saturation, color gradation, contrast, or brightness associated with the coverage of the contaminant (e.g., residue 105) coated over thermal distributor 140. In some embodiments, the process of determining the impurity characteristics can include measuring the visual signature of a portion of chamber 160's sides proximate to chuck 104.

In some embodiments, the process of determining the impurity characteristic can include collecting an optical signature of elements in process module 102. For example, the process of determining the impurity characteristic can include (i) emitting an optical signal towards thermal distributor 140; and (ii) measuring a reflected or scattered optical signal from thermal distributor 140. Based on a wavelength of the emitted and the measured optical signals, the surface coverage and/or the thickness of the contaminants (e.g., residue 105) coated over thermal distributor 140 can be inferred by calculating an intensity difference or a phase difference between the emitted and the measured optical signal. The optical emission, the optical measurement, and the calculation of intensity/phase difference can be conducted by detection module 126. In some embodiments, the calculation can be conducted by a computer system (e.g., controller unit 170).

In some embodiments, the process of determining the impurity characteristic can include measuring an amount of material deposited by deposition processes conduced by processing module 102. As previously discussed, showerhead 106 can provide a processing gas, such as tungsten hexafluoride, to deposit a layer of material (not shown in FIG. 1), such as a tungsten film, associated with the processing gas on substrate 111, while showerhead 106 can concurrently and unintentionally coat a layer of material 105 (e.g., residue 105), such as a tungsten residue, associated with the processing gas over thermal distributor 140. Accordingly, an cumulative amount of the layer of material (e.g., tungsten film) deposited by processing module 102 can be positively correlated to the surface coverage of a contaminant (e.g., residue 105) coated over thermal distributor 140. In some embodiments, the process of measuring the cumulative amount of material deposited by processing module 102 can include (i) measuring a flow rate and a flow time of a processing gas associated with each deposition process conducted by processing module 102, via a gas flow controller (not shown in FIGS. 1-3) of gas supply system 112; and (ii) determining the cumulative amount of material deposited by processing module 102 by calculating a weighted sum of the process gas's flow rate (e.g., weights of the weight sum can be the flow time of the process gas).

In operation 320 of FIG. 3, the impurity characteristic is compared to a baseline characteristic. The baseline characteristic can be associated with a surface cleanliness requirement for thermal distributor 140 to ensure thermal distributor 140's capability to maintain substrate 111's temperature uniformity, thus maintaining a production yield requirement of the deposition process conducted by processing module 102. The baseline characteristic can include a predefined thermal signature of thermal distributor 140 (e.g., a predefined surface temperature of thermal distributor 140 that can provide a qualified temperature uniformity for substrate 111), a predefined visual signature of thermal distributor 140 (e.g., an image of thermal distributor 140 without adhesion of residue 105), a predefined upper limit of surface coverage and/or thickness of residue 105 coated over thermal distributor 140, or a predefined upper limit the cumulative amount of material deposited by processing module 102.

The process of comparing the impurity characteristic to the baseline characteristic can include subtracting the baseline characteristic from the impurity characteristic. For example, the impurity characteristic can be a temperature of thermal distributor 140 collected by operation 310, where the process of comparing can include subtracting the temperature of thermal distributor 140 from the predefined temperature threshold. In some embodiments, the impurity characteristic can be an average of a group of temperatures of thermal distributor 140 collected by operation 310, where the process of comparing can include subtracting the average of the group of temperatures of thermal distributor 140 from the predefined temperature threshold. In some embodiments, the impurity characteristic can be a median of a group of temperatures of thermal distributor 140 collected by operation 310, where the process of comparing can include subtracting the median of the group of temperatures of thermal distributor 140 from the predefined temperature threshold. In some embodiments, the impurity characteristic can be an maximum of a group of temperatures of thermal distributor 140 collected by operation 310, where the process of comparing can include subtracting the maximum of the group of temperatures of thermal distributor 140 from the predefined temperature threshold. In some embodiments, the impurity characteristic can be an minimum of a group of temperatures of thermal distributor 140 collected by operation 310, where the process of comparing can include subtracting the minimum of the group of temperatures of thermal distributor 140 from the predefined temperature threshold. In some embodiments, the impurity characteristic can be an image (e.g., a visual signature) of thermal distributor 140 collected by operation 310, where the process of comparing can include pixel subtraction between the collected image and the predefined image of thermal distributor 140 without adhesion of residue 105. In some embodiments, the impurity characteristic can be a surface coverage/thickness of the contaminants (e.g., residue 105) coated over thermal distributor 140 collected by operation 310, where the process of comparing can include subtracting the determined surface coverage/thickness of the contaminants (e.g., residue 105) coated over thermal distributor 140 from the predefined upper limit of surface coverage/thickness. In some embodiments, the process of comparing can include subtracting the determined cumulative amount of material deposited by processing module 102 from the predefined upper limit of the amount of material deposited by processing module 102. In some embodiments, the process of comparing can be performed by a computer system (e.g., controller unit 170). In some embodiments, details of operation 320 can at least be referred to the description of controller unit 170 shown at FIG. 1.

In operation 330 of FIG. 3, a decontamination process is conducted in processing module 102 based on the comparison in operation 320. The decontamination process can include determining the decontamination gas based on the material of the contaminants (e.g., residue 105) coated in chamber 160. For example, residue 105 can be a tungsten residue coated over thermal distributor 140, where the decontamination gas can be determined, via controller unit 170 and/or gas extraction system 112, to be a gas of nitrogen trifluoride, a plasma of nitrogen trifluoride, an atomic beam of nitrogen trifluoride, a molecular beam of nitrogen trifluoride, or a radical of nitrogen trifluoride. The decontamination process can further include supplying the determined decontamination gas, via gas scrubbing device 130, to chamber 160 to remove the contaminants (e.g., residue 105) from thermal distributor 140 based on the comparison in operation 320. For example, controller unit 170 can instruct gas scrubbing device 130 to supply the decontamination gas for a length of time to decontaminate the contaminants from thermal distributor 140, where the length of time can be determined, via controller unit 170, based on the comparison in operation 320. In some embodiments, the length of time for supplying the decontamination gas can be positively correlated (e.g., a linear relationship) to the difference, determined by operation 320, between the measured temperature of thermal distributor 140 and the predefined temperature threshold. In some embodiments, controller unit 170 can instruct gas scrubbing device 130 to supply the decontamination gas with a flow rate to decontaminate the contaminants from thermal distributor 140, where the flow rate can be determined, via controller unit 170, based on the comparison in operation 320. In some embodiments, the flow rate for supplying the decontamination gas can be positively correlated (e.g., a linear relationship) to the difference, determined by operation 320, between the measured temperature of thermal distributor 140 and the predefined temperature threshold. In some embodiments, controller unit 170 can instruct gas scrubbing device 130 to supply the decontamination gas associated with a radio frequency (RF) power/voltage of remote plasma source 108 to decontaminate the contaminants from thermal distributor 140, where the RF power/voltage of remote plasma source 108 can be determined, via controller unit 170, based on the comparison in operation 320. In some embodiments, the RF power/voltage can be positively correlated (e.g., a linear relationship) to the difference, determined by operation 320, between the measured temperature of thermal distributor 140 and the predefined temperature threshold. In some embodiments, details of operation 330 can at least be referred to the description of gas scrubbing device 130 shown at FIG. 1.

In operation 340 of FIG. 3, a production yield associated with the processing module is determined, and the production yield is compared to a baseline manufacturing standard. The process of determining the production yield can include (i) conducting a deposition process, via processing module 102, to deposit a film over substrate 111, (ii) measuring a surface morphology (e.g., one or more film thicknesses at different locations, thickness uniformity, surface roughness, and/or a particle counts) or an electrical characteristic (e.g., sheet resistance) of the film deposited over substrate 111, and (iii) calculating the average, the median, the maximum, or the minimum of the surface morphology to determine the production yield associated with processing module 102; or calculating the average, the median, the maximum, or the minimum of the electrical characteristic to determine the production yield associated with processing module 102. The process of comparing the impurity characteristic to the baseline manufacturing standard can include calculating a difference between the determined production yield and the baseline manufacturing standard. The baseline manufacturing standard can be a predefined yield threshold associated with a qualified manufacturing requirement for processing module 102. In some embodiments, the baseline manufacturing standard can include a predefined film thickness, a predefined film thickness uniformity, a predefined film surface roughness, a predefined particle count, and/or a predefined sheet resistance. In some embodiments, details of operation 340 can at least be referred to the description of processing module 102 shown at FIG. 1.

In operation 350 of FIG. 3, one or more operations of processing module 102 are adjusted based on the comparison in operation 340 (e.g., the comparison between the production yield and the baseline manufacturing standard of operation 340). In some embodiments, the adjustment can include (i) updating the baseline characteristic based on the comparison in operation 340, and (ii) proceeding to operation 310 to continue monitoring contaminants (e.g., residue 105) in processing module 102. For example, in response to the production yield determined in operation 340 being less than the baseline manufacturing standard (e.g., thickness uniformity of the film deposited over substrate 111 is less than a predefined thickness uniformity), the adjustment can include increasing the predefined temperature threshold (e.g., the baseline characteristic in operation 320) and proceeding to operation 310, where the increased predefined temperature threshold can remove residue 105 from thermal distributor 140. In some embodiments, details of operation 350 can at least be referred to the description of processing module 102 shown at FIG. 1.

In some embodiments, in response to the production yield determined in operation 240 being greater than or substantially equal to the baseline manufacturing standard (e.g., thickness uniformity of the film deposited over substrate 111 being greater than or substantially equal to a predefined thickness uniformity), the adjustment can include maintaining the predefined temperature threshold (e.g., the baseline characteristic in operation 320) and proceeding to operation 310. In some embodiments, in response to the production yield determined in operation 340 being greater than or substantially equal to the baseline manufacturing standard (e.g., thickness uniformity of the film deposited over substrate 111 being greater than or substantially equal to a predefined thickness uniformity), the adjustment can include decreasing the predefined temperature threshold (e.g., the baseline characteristic in operation 320) and proceeding to operation 310, where the decreased temperature threshold can reduce the usage of the decontamination gas at the next iteration of method 300.

In some embodiments, in response to the production yield determined in operation 340 being less than the baseline manufacturing standard (e.g., thickness uniformity of the film deposited over substrate 111 is less than a predefined thickness uniformity), the adjustment can include conducting a manually-controlled decontamination process (e.g., supplying the decontamination gas with a manually-controlled flow rate and/or a manually controlled flow time) to further decontaminate thermal distributor 140 in processing module 102 and proceeding to operation 340 to reevaluate the production yield of processing module 102.

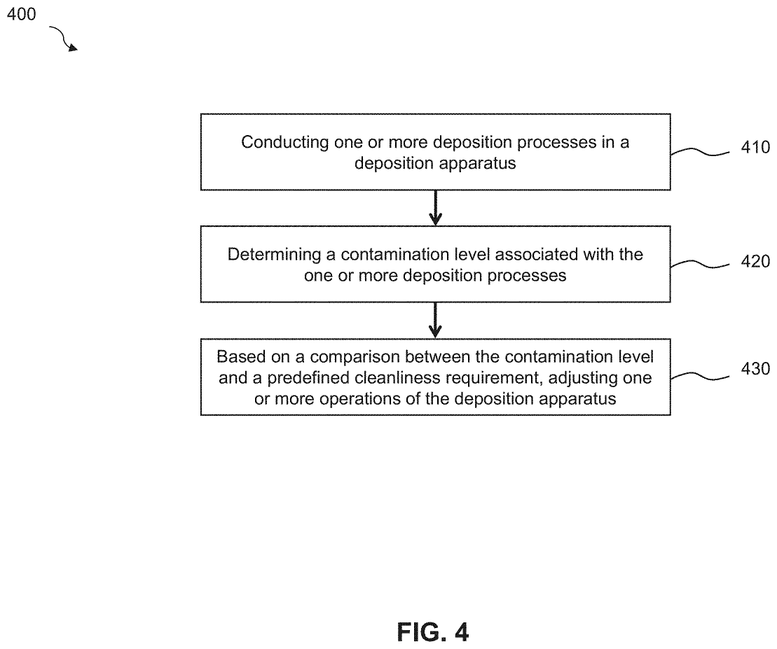

FIG. 4 is a method 400 for operating a deposition apparatus (e.g., semiconductor device manufacturing apparatus 100), according to some embodiments of the present disclosure. Operations shown in method 400 are not exhaustive; other operations can be performed before, after, or between any of the illustrated operations. In some embodiments, operations of method 400 can be performed in a different order. Variations of method 400 are within the scope of the present disclosure.

Method 400 begins with operation 410, where one or more deposition processes are conducted in the deposition apparatus. Each of the one or more deposition processes can include placing substrate 111 on chuck 104 of processing module 102, supplying a processing gas towards substrate 111 through showerhead 106, and heating, via chuck 104, substrate 111 to a suitable deposition process temperature. After each of the one or more deposition processes, a film can be deposited on substrate 111, while the respective residue 105 can be deposited in the deposition apparatus, such as being deposited over thermal distributor 140. In some embodiments, details of operation 410 can at least be referred to the description of processing module shown at FIG. 1.

In operation 420, a contamination level associated with the one or more deposition processes is determined. The contamination level can be determined by cumulatively summing multiple individual residue 105's levels, associated with each of the one or more deposition processes, deposited on thermal distributor 140. Each of the individual residue 105's levels can be associated with a usage of the respective processing gas of each of the one or more deposition processes. In some embodiments, a usage of a processing gas of a deposition process can be determined by measuring a volume of the processing gas consumed by the deposition process, where the volume can be further determined by measuring a flow rate and a flow time of the processing gas during the deposition process. In some embodiments, a usage of a processing gas can be determined by measuring a weight of the processing gas consumed by the deposition process, where the weight can be determined based on the measured volume, the processing gas's molecular weight or atomic weight, and the processing gas's density. Each individual residue 105's level can further be associated with a sticking coefficient of the respective processing gas during the deposition process. For example, a processing gas with a higher sticking coefficient during a deposition process can introduce a higher residue 105's level in the deposition apparatus. In some embodiments, the sticking coefficient of a processing gas during a deposition process can be determined based on the temperature associated with the deposition process and/or based on an operating pressure associated with the deposition process. Accordingly, the determination of the contamination level can include calculating a cumulative weighted sum based on the sticking coefficients and the usages of the processing gases in each deposition process performed by the deposition apparatus. In some embodiments, the determination of the contamination level can at least be referred to the description of FIG. 2.

In operation 430, one or more operations of the deposition apparatus are adjusted based on a comparison between the contamination level and a predefined cleanliness requirement. In response to the contamination level being higher than the predefined cleanliness requirement, the adjustments can include removing contaminants from the thermal distributor 140 of processing module 102. In some embodiments, the removal of the contaminants can include supplying a decontamination gas, via gas scrubbing device 130, to chamber 160 to remove the contaminants (e.g., residue 105) from thermal distributor 140. In some embodiments, the adjustment can include aborting an on-going deposition process. For example, in response to the contamination being higher than the predefined cleanliness, processing module 102 may continue performing an on-going deposition process to meet a manufacturing schedule and a subsequent deposition processes can be aborted to avoid potential manufacturing yield concerns associated with the contamination. The adjustment can further include interlocking the operations of the deposition apparatus, such as triggering a preventive maintenance alert to hand-wash the deposition apparatus's thermal distributor 140, prohibiting the use of processing gas with a high sticking coefficient, and/or adjusting a manufacturing schedule of a semiconductor device using the deposition apparatus. For example, the adjustment can notify supply-chain management to prepare an inventory of a new decontamination gas to further decontaminate the deposition apparatus.

Further, after operation 430, the contamination level can be reset based on the adjustment of one or more operations in operation 430. For example, the contamination level can be reset to zero if the decontamination gas substantially removes the contaminants (e.g., the contaminants are completely removed by operation 430.) In some embodiments, the contamination level can be reset to a fraction of the original contamination level (e.g., the contaminants are partially removed by operation 430.)

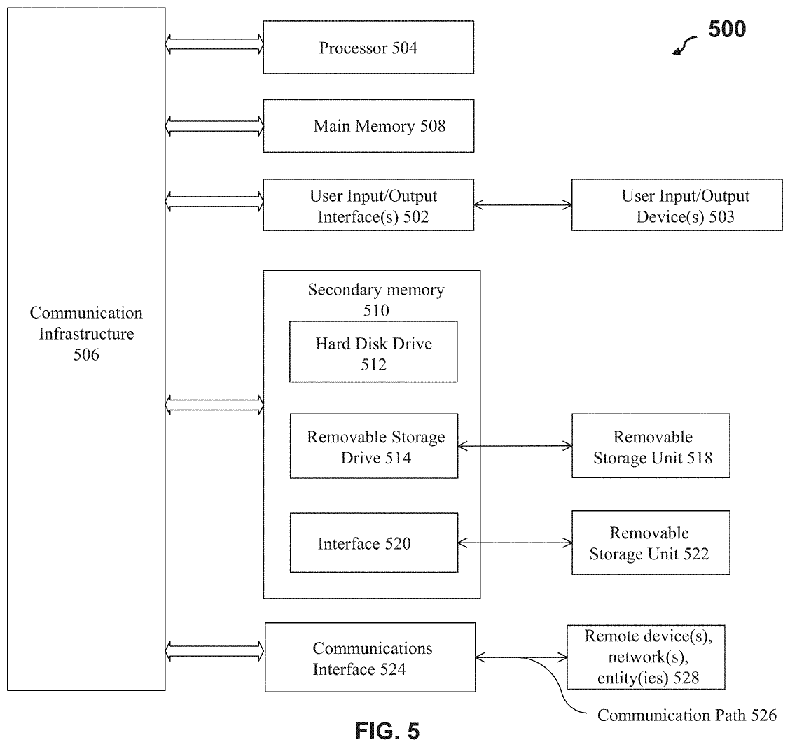

FIG. 5 is an illustration of an example computer system 500 in which various embodiments of the present disclosure can be implemented, according to some embodiments. Computer system 500 can be used, for example, in controller unit 170 of FIG. 1. Computer system 500 can be any well-known computer capable of performing the functions and operations described herein. Computer system 500 can be used, for example, to execute one or more operations of semiconductor device manufacturing apparatus 100 and/or methods 300 and 400.

Computer system 500 includes one or more processors (also called central processing units, or CPUs), such as a processor 504. Processor 504 is connected to a communication infrastructure or bus 506. Computer system 500 also includes input/output device(s) 503, such as monitors, keyboards, pointing devices, etc., that communicate with communication infrastructure or bus 506 through input/output interface(s) 502. A control tool can receive instructions to implement functions and operations described herein—e.g., the functions of semiconductor device manufacturing apparatus 100 described in FIG. 1 and the method/process described in FIGS. 3 and 4—via input/output device(s) 503. Computer system 500 also includes a main or primary memory 508, such as random access memory (RAM). Main memory 508 can include one or more levels of cache. Main memory 508 has stored therein control logic (e.g., computer software) and/or data. In some embodiments, the control logic (e.g., computer software) and/or data can include one or more of the functions described above with respect to semiconductor device manufacturing apparatus 100. In some embodiments, processor 504 can be configured to execute the control logic stored in main memory 508.

Computer system 500 can also include one or more secondary storage devices or memory 510. Secondary memory 510 can include, for example, a hard disk drive 512 and/or a removable storage device or drive 514. Removable storage drive 514 can be a floppy disk drive, a magnetic tape drive, a compact disk drive, an optical storage device, tape backup device, and/or any other storage device/drive.

Removable storage drive 514 can interact with a removable storage unit 518. Removable storage unit 518 includes a computer usable or readable storage device with computer software (control logic) and/or data stored thereon. Removable storage unit 518 can be a floppy disk, magnetic tape, compact disk, DVD, optical storage disk, and/any other computer data storage device. Removable storage drive 514 reads from and/or writes to removable storage unit 518 in a well-known manner.

According to some embodiments, secondary memory 510 can include other mechanisms, instrumentalities or other approaches for allowing computer programs and/or other instructions and/or data to be accessed by computer system 500. Such mechanisms, instrumentalities or other approaches can include, for example, a removable storage unit 522 and an interface 520. Examples of the removable storage unit 522 and the interface 520 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 510, removable storage unit 518, and/or removable storage unit 522 can include one or more of the functions described above with respect to the wet bench structure.

Computer system 500 can further include a communication or network interface 324. Communication interface 524 enables computer system 500 to communicate and interact with any combination of remote devices, remote networks, remote entities, etc. (individually and collectively referenced by reference number 528). For example, communication interface 524 can allow computer system 500 to communicate with remote devices 528 over communications path 526, which can be wired and/or wireless, and which can include any combination of LANs, WANs, the Internet, etc. Control logic and/or data can be transmitted to and from computer system 500 via communication path 526.

The functions/operations in the preceding embodiments can be implemented in a wide variety of configurations and architectures. Therefore, some or all of the operations in the preceding embodiments—e.g., the functions of semiconductor device manufacturing apparatus 100 described in FIG. 1 and the method/process described in FIGS. 3 and 4—can be performed in hardware, in software or both. In some embodiments, a tangible apparatus or article of manufacture including a tangible computer useable or readable medium with control logic (software) stored thereon is also referred to herein as a computer program product or program storage device. This includes, but is not limited to, computer system 500, main memory 508, secondary memory 510 and removable storage units 518 and 522, as well as tangible articles of manufacture embodying any combination of the foregoing. Such control logic, when executed by one or more data processing devices (such as computer system 500), causes such data processing devices to operate as described herein. For example, the hardware/equipment can be connected to or be part of element 528 (remote device(s), network(s), entity(ies) 528) of computer system 500.

The present disclosure provides a deposition apparatus and a method to improve production yield for a semiconductor device manufacturing process. The deposition apparatus can include a chuck configured to hold a substrate and a showerhead configured to conduct the deposition process on the substrate. The deposition apparatus can further include a thermal distributor configured to enhance the substrate's temperature uniformity, a gas scrubbing device configured to decontaminate the thermal distributor, and a detection module configured to monitor a cleanliness of the thermal distributor's surface. In some embodiments, the gas scrubbing device can be disposed over a backside of the thermal distributor, where the showerhead can be disposed over a front side of the thermal distributor. The deposition apparatus can further include a controller unit configured to conduct the deposition process. The controller can further be configured to conduct a decontamination process to decontaminate the thermal distributor by instructing the detection module and the gas scrubbing device. A benefit of the deposition apparatus and the method, among others, is to improve the thickness uniformity of the film deposited by the deposition process, thus enhancing an overall yield of the semiconductor device manufacturing on the substrate.

In some embodiments, a semiconductor device manufacturing apparatus can include a deposition apparatus and a processor. The deposition apparatus can include a chamber, a detection module configured to detect impurities in the chamber, and a gas scrubbing device configured to remove the impurities. The processor can be configured to (i) receive, from the detection module, an impurity characteristic associated with the impurities; (ii) compare the impurity characteristic to a baseline characteristic; and (iii) instruct the gas scrubbing device to supply a decontamination gas in the chamber based on the comparison of the impurity characteristic to the baseline characteristic.

In some embodiments, a semiconductor device manufacturing apparatus can include a deposition apparatus and a processor. The deposition apparatus can include a chuck configured to hold a substrate, a thermal distributor configured to control a temperature uniformity of the substrate, a detection module configured to detect a characteristic associated with an impurity on the thermal distributor, and a gas scrubbing device configured to reduce the impurity. The thermal distributor can be disposed under the chuck. The processor can be configured to (i) receive, from the detection module, the characteristic associated with the impurity; (ii) compare the characteristic associated with the impurity to a baseline characteristic; and (iii) instruct the gas scrubbing device to supply a decontamination gas based on the comparison of the characteristic associated with the impurity to the baseline characteristic.

In some embodiments, a method can include (i) conducting a deposition process, via a deposition apparatus, to deposit a film of a material; (ii) determining a contamination characteristic associated with a residue of the material on the deposition apparatus; (iii) comparing the contamination characteristic to a baseline characteristic; and (iv) based on the comparison, conducting a decontamination process to remove the residue of the material on the deposition apparatus.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device manufacturing apparatus, comprising:
a deposition apparatus, comprising:
a chamber;
a detection module configured to detect impurities in the chamber; and
a gas scrubbing device configured to remove the impurities; and
a processor configured to:
receive, from the detection module, an impurity characteristic associated with the impurities;
compare the impurity characteristic to a baseline characteristic; and
instruct the gas scrubbing device to supply a decontamination gas in the chamber based on the comparison of the impurity characteristic to the baseline characteristic.

2. The semiconductor device manufacturing apparatus of claim 1, wherein the detection module comprises a fiber sensor configured to detect a temperature signature associated with the impurities in the chamber.

3. The semiconductor device manufacturing apparatus of claim 1, wherein the detection module comprises an image sensor configured to detect a visual signature associated with the impurities in the chamber.

4. The semiconductor device manufacturing apparatus of claim 1, wherein the gas scrubbing device comprises an opening and a plasma generator coupled to the opening, and wherein the opening is formed through a side of the chamber.

5. The semiconductor device manufacturing apparatus of claim 1, wherein the deposition apparatus further comprises:
a chuck housed in the chamber; and
a showerhead disposed over the chuck;
wherein the gas scrubbing device is disposed under the chuck.

6. The semiconductor device manufacturing apparatus of claim 5, wherein the deposition apparatus further comprises a remote plasma source, wherein the remote plasma source is coupled to the showerhead and the gas scrubbing device.

7. The semiconductor device manufacturing apparatus of claim 1, wherein the deposition apparatus further comprises a chuck, wherein a first side of the chuck is configured to hold a substrate, and wherein the gas scrubbing device is disposed under a second side, opposite to the first side, of the chuck.

8. A semiconductor device manufacturing apparatus, comprising:
a deposition apparatus, comprising:
a chuck configured to hold a substrate;
a thermal distributor configured to control a temperature uniformity of the substrate, wherein the thermal distributor is disposed under the chuck;
a detection module configured to detect a characteristic associated with an impurity on the thermal distributor; and
a gas scrubbing device configured to reduce the impurity; and
a processor configured to:
receive, from the detection module, the characteristic associated with the impurity;
compare the characteristic associated with the impurity to a baseline characteristic; and
instruct the gas scrubbing device to supply a decontamination gas based on the comparison of the characteristic associated with the impurity to the baseline characteristic.

9. The semiconductor device manufacturing apparatus of claim 8, wherein the detection module comprises a fiber sensor configured to detect a temperature signature associated with the impurity on the thermal distributor.

10. The semiconductor device manufacturing apparatus of claim 8, wherein the detection module comprises an image sensor configured to detect a visual signature associated with the impurity on the thermal distributor.

11. The semiconductor device manufacturing apparatus of claim 8, wherein the gas scrubbing device comprises:
an opening under the chuck; and
a remote plasma source coupled to the opening.

12. The semiconductor device manufacturing apparatus of claim 8, wherein the deposition apparatus further comprises a showerhead disposed over the chuck and configured to provide a processing gas to deposit a material film on the substrate.

13. The semiconductor device manufacturing apparatus of claim 12, wherein the deposition apparatus further comprises a remote plasma source coupled to the showerhead and the gas scrubbing device.

14. The semiconductor device manufacturing apparatus of claim 8, wherein the deposition apparatus further comprises a chamber to house the thermal distributor, and wherein the detection module is disposed outside the chamber.

15. A method, comprising:
conducting a deposition process, via a deposition apparatus, to deposit a film of a material;
determining a contamination characteristic associated with a residue of the material on the deposition apparatus;
comparing the contamination characteristic to a baseline characteristic; and
based on the comparison, conducting a decontamination process to remove the residue of the material on the deposition apparatus.

16. The method of claim 15, wherein conducting the deposition process comprises depositing a metallic material.

17. The method of claim 15, wherein determining the contamination characteristic comprises collecting a visual signature of the residue of the material on the deposition apparatus.

18. The method of claim 15, wherein determining the contamination characteristic comprises measuring one or more temperatures of a thermal distributor of the deposition apparatus.

19. The method of claim 18, wherein comparing the contamination characteristic comprises:
calculating an average of the one or more temperatures; and
calculating a difference between a pre-determined temperature threshold and the average of the one or more temperatures.

20. The method of claim 15, wherein conducting the decontamination process comprises:
determining a flow time of a decontamination gas based on the comparison; and
supplying the decontamination gas, for a period of the flow time, to the deposition apparatus.
